(19) United States
(12) Patent Application Publication
(10) Pub. No.: US 2026/0052684 A1
(43) Pub. Date: Feb. 19, 2026

(54) CAPACITOR BASED ON EFLASH ARCHITECTURE AND METHOD OF MANUFACTURING THE SAME

(71) Applicant: UNITED MICROELECTRONICS CORP., Hsin-Chu City (TW)

(72) Inventors: Seo Jun Lee, Singapore (SG); Xiang Li, Singapore (SG); Ding Lung Chen, Singapore (SG)

(73) Assignee: UNITED MICROELECTRONICS CORP., Hsin-Chu City (TW)

(21) Appl. No.: 18/829,309

(22) Filed: Sep. 10, 2024

(30) Foreign Application Priority Data
Aug. 13, 2024 (TW) 113130324

(51) Int. Cl. H10B 41/30

(52) U.S. Cl. CPC H10B 41/30

(57) ABSTRACT

A capacitor based on eFlash architecture is provided in the present invention, including a first word line, a second word line and a third word line on a substrate, a continuous first floating gate between the first word line and the second word line, a continuous second floating gate between the second word line and the third word line, multiple first contacts connected on the word lines and multiple second contacts connected on the floating gates, wherein the capacitor is in reflection symmetric with respect to the second word line.

### BACKGROUND OF THE INVENTION

### 1. Field Of The Invention

The present invention relates generally to a capacitor, more specifically, to a capacitor based on eFlash architecture and method of manufacturing the same.

### 2. Description Of The Prior Art

A digital-to-analog converter (DAC) is a device that converts digital signals into analog signals in the form of current, voltage or charge. In many digital systems, signals are stored and transmitted in a digitized form. DAC can convert such signals into analog signals so that they can be recognized by external users like humans or other non-digital systems. Analog-to-Digital converter (ADC), on the contrary, converts analog signals into digital signals, which is commonly used in communication systems, measuring instruments and computer systems, such as image signal processors (ISP) in CMOS image sensors. ADC can convert the sensed analog image signals (such as voltage signals) into digital signals so these signals can be compared and processed by processor later.

High-resolution ADC is usually provided with capacitors, for example MOS capacitors, functioning as one of components in comparator for the process of comparing signals. The advantage of MOS capacitors lies that they can be manufactured in semiconductor FEOL process (front-end-of-line), and may significantly reduce necessary layout area on silicon wafer. However, the capacitance of MOS capacitor is easily affected by the applied voltage (voltage dependent), making its C-V curve highly non-linear, thereby resulting in high differential non-linearity (DNL) in image processing that is unable to meet the requirement of current high-resolution image sensors.

### SUMMARY OF THE INVENTION

In the light of current MOS capacitors incapable of meeting the requirement of high-resolution image sensors, the present invention hereby provides a novel capacitor, featuring an eFlash-based architecture that can be adopted and integrated in semiconductor FEOL of eFlash process for manufacture purpose, achieving highly-integrated layout without additional photomasks or process steps, and its capacitance characteristics is voltage independent, meeting the requirement of current advanced high-resolution image sensors.

One aspect of the present invention is to provide a capacitor based on eFlash architecture, including: a substrate; a first word line, a second word line and a third word line arranged sequentially on the substrate and extending in a first direction; a first floating gate between the first word line and the second word line and extending continuously in the first direction across a whole range of the first word line and the second word line; a second floating gate between the second word line and the third word line and extending continuously in the first direction across a whole range of the second word line and the third word line; multiple capacitive dielectric layers between the three word lines and the two floating gates; multiple first contacts connected on the first word line, the second word line and the third word line; and multiple second contacts connected on the first floating gate and the second floating gate; wherein the capacitor is in reflection symmetry with respect to the second word line, and the second direction is perpendicular to the first direction.

Another aspect of the present invention is to provide a method of manufacturing a capacitor based on eFlash, including: providing a substrate; forming a gate insulating layer, a floating gate material layer, an inter-gate dielectric layer and a control gate material layer sequentially on the substrate; performing a first photolithography process to pattern the control gate material layer and the inter-gate dielectric layer, so as to form a control gate layer stack, wherein control gates are included in the control gate layer stack; forming first spacers on sidewalls of the control gate layer stack; performing an etching process using the control gate layer stack and the first spacers as a mask to pattern the floating gate material layer, so as to form a first floating gate and a second floating gate; forming capacitive dielectric layers on sidewalls of the first spacers and the two floating gates; forming a first word line and a third word line at outer sides of the two floating gates and forming a second word line between the two floating gates; removing the control gates and the inter-gate dielectric layers on the two floating gates; forming an interlayer dielectric layer covering the three word lines and the two floating gates on the substrate; and forming first contacts and second contacts in the interlayer dielectric layer, the first contacts are connected on the three word lines, and the second contacts are connected on the two floating gates.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic cross-section of a capacitor based on eFlash in accordance with the preferred embodiment of present invention;

FIG. 2 is a schematic top view of the capacitor based on eFlash in accordance with the preferred embodiment of present invention; and

FIGS. 3-12 are schematic cross-sections of the capacitor based on eFlash in accordance with the preferred embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). In addition, spatially relative terms (e.g., “beneath,” “below,” “lower,” “above,” “upper” and the like) may be used herein for ease of description to describe one element or a relationship between a feature and another element or feature as illustrated in the figures.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

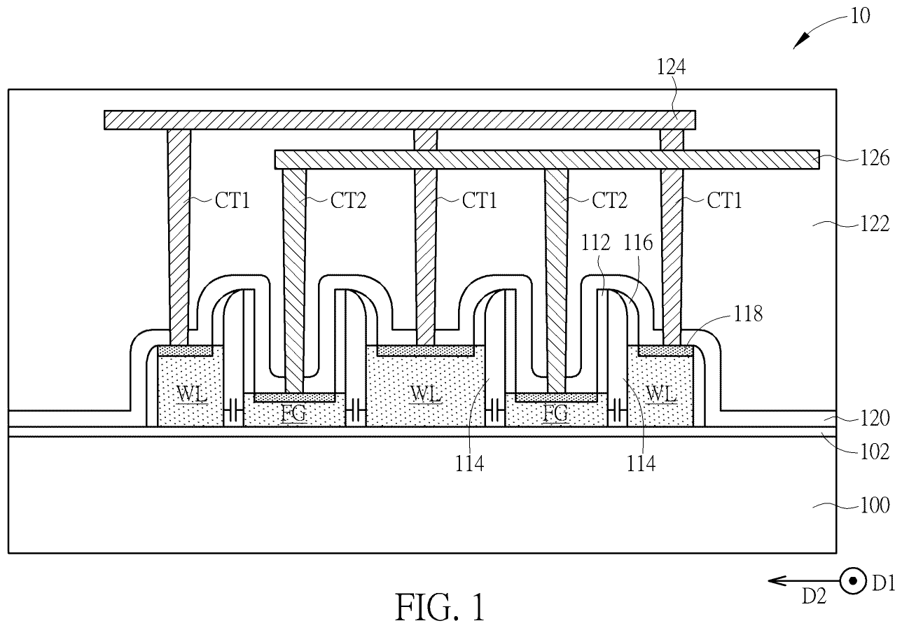

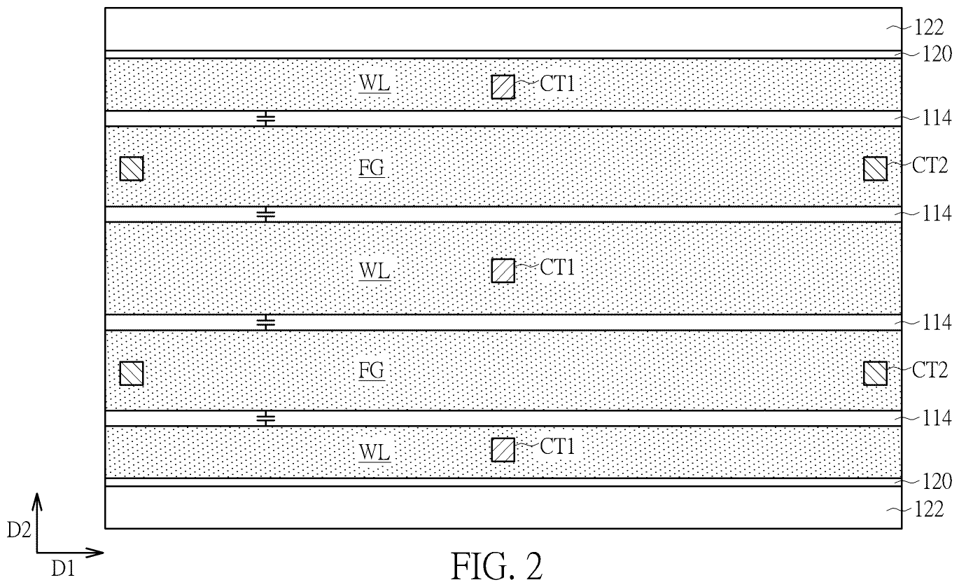

Please refer to FIG. 1 and FIG. 2 collectively, which are schematic cross-section and top view of a capacitor based on eFlash in the preferred embodiment of present invention. These two figures can provide a thorough comprehension for readers about the layout planes, relative positions and interconnections therebetween in vertical direction of the components in the capacitor of present invention. The capacitor provided in the present invention is designed based on the architecture of eFlash (embedded Flash), which adopts currently available eFlash process to integrally manufacture the storage devices of eFlash in cell region and the logic devices in logic region, without additional photomasks and process steps. Since the subject of present invention is capacitor based on eFlash, all subsequent figures will show only the capacitor area. Description about the components and features in other region will be omitted as much as possible to avoid obscuring the focus of present invention, which is explained herein in advance.

As shown in the figure, the capacitor 10 of present invention is set on a semiconductor substrate 100. The semiconductor substrate 100 is preferably a silicon (Si) substrate, ex. a p-type doped Si wafer. Other Si-based substrates may also be adopted, for example group [symbol] compound on Si substrate (ex. GaN-on-silicon), SOI substrate (silicon-on-insulator) or substrate with other doping types, but not limited thereto. Multiple doped regions may be formed in the semiconductor substrate 100 through ion implantation process, for example N-well, P-well, source, drain and LDD (lightly doped drains) for various devices, with STIs (shallow trench isolations) formed thereon to define multiple active areas (AAs), ex. cell array for eFlash. Since the capacitor of present invention is not related to these doped regions, they will not be shown in following figures. In addition, since it is not required to define individual active areas for floating gates in the capacitor of present invention, STIs may not be formed in the semiconductor substrate 100. However, in the case of being manufactured integrally with other devices, the aforementioned doped regions and STIs may be formed in the capacitor region of semiconductor substrate 100, but not limited thereto.

Please refer to FIG. 1 and FIG. 2. The semiconductor substrate 100 is provided with a gate insulating layer 102 formed on entire surface of capacitor region, functioning as an insulating layer between the semiconductor substrate 100 and various gate structures (ex. floating gate, word line or logic gate) thereon. In the embodiment of present invention, the gate insulating layer 102 may also be a tunnel oxide layer for eFlash storage device, with material like silicon oxide. In the embodiment of present invention, the capacitor 10 includes three word lines WL and two floating gates FG between those word lines WL. The three word lines WL and two floating gates FG are spaced apart in a second direction D2 and extend in a first direction D1 (longitudinal direction). Please note that, different from the design of segmental floating gate in ordinary eFlash cell array, the floating gate FG of capacitor 10 in the present invention extends in the first direction D1 across a whole range of the word line WL, meaning the lengths of word line WL and floating gate FG in the first direction D1 are substantially the same and completely overlap with each other. The material of word line WL and floating gate may be polysilicon, with N-type dopants (ex. phosphorus (P), Arsenic (As) or antimony (Sb)) heavily doped therein to improve its conductivity.

Refer still to FIG. 1 and FIG. 2. In the embodiment of present invention, the height of word line WL is higher than the height of floating gate FG, and a capacitive dielectric layer 114 is intermediate between the word line WL and floating gate FG. As shown in the figure, the material of capacitive dielectric layer 114 may be silicon oxide, which extends upwardly in a direction vertical to the substrate above the height of word line WL and floating gate FG. A first spacer 112 and a second spacer 116 are further provided at two sides of the capacitive dielectric layer 114 respectively in the second direction D2, which are respectively on top planes of the floating gate FG and word line WL. The second spacers 116 are further on outer sidewalls of the two word lines in the second direction D2. The material of first spacer 112 and second spacer 116 may be silicon oxide, silicon nitride or the multilayer structure thereof. In the embodiment, the first spacer 112 and second spacer 116 are components formed in eFlash process, wherein self-aligned metal silicide layers 118 (ex. nickel silicides, NiSi) are formed on top planes of the word lines WL and floating gates FG that are not covered by the first spacers 112 and second spacers 116, to reduce series resistance between Si-based floating gates FG and word lines and metal-based contacts CT1, CT2. Please note that, for the conciseness of drawings, the aforementioned first spacers 112, second spacers 116 and metal silicide layers 118 are not shown in the top view of FIG. 2. It can be seen in the figure that the whole capacitor 10 of present invention is in reflection symmetry with respect to a middle word line WL in the second direction D2.

Refer still to FIG. 1 and FIG. 2. In addition to the components above, the capacitor 10 may further include a liner 120 and an ILD (interlayer dielectric) layer 122, wherein the material of liner 120 may be silicon nitride, conformally formed on surfaces of the aforementioned components and covering the metal silicide layers 118 on top planes of the floating gates FG and word lines WL. The material of ILD layer 122 may be TEOS (tetraethoxysilane), which is on the liner 120, covering the whole capacitor 10 and filling up the recesses therein, so as to provide a flat process surface. In the embodiment of present invention, contacts CT1, CT2 are formed in the ILD layer 122, with material like tungsten (W). Contacts CT1, CT2 extend downwardly in the direction vertical to the substrate through the liner 120, respectively connected to the metal silicide layers 118 on the word lines WL and floating gates FG, and connected upwardly to a metal line 124 and a metal line 126. The material of metal line 124 and metal line 126 may be copper (Cu) or aluminum (Al), which may be parts of semiconductor BEOL (back-end-of-line) interconnects. It can be seen in the figure that the three word line WL in the capacitor 10 are connected respectively to a common metal line 124 through corresponding contacts CT1, and the two floating gates FG in the capacitor 10 are connected respectively to a common metal line 126 through corresponding contacts CT2. The contacts CT1 are aligned in the second direction D2 and the contacts CT2 are aligned in the second direction D2 from top view, but not limited thereto.

In an operation, different voltages are applied on the word lines WL and the floating gates FG of capacitor 10 respectively through contacts CT1, CT2 and metal lines 124, 126. Parallel word lines and floating gates FG function as conductive planes at two terminals of a capacitor with the capacitive dielectric layer 114 isolating therebetween. Due to electric field, positive charges and negative charges are generated respectively on word line WL and floating gate FG at two terminals, so as to form a capacitor. One advantage of present invention is that its principle is similar to the one of MOS capacitor, which may be manufactured in semiconductor FEOL process (ex. eFlash process), thereby reducing necessary layout area on Si wafer significantly and achieving high density of integration. Another advantage of present invention is that heavily doped word lines WL and floating gates FG may form a capacitor in accumulation mode, which is voltage independent, rendering the C-V curve highly linear to fulfill the requirement of high-resolution image sensor.

On the other hand, although both of them can be manufactured in eFlash process, please note that the capacitor 10 of present invention is distinguished from conventional eFlash memory structure. In common eFlash architecture, it is an erase gate (EG) rather than a word line WL set between the two floating gates FG, for controlling the release of charges trapped in the floating gates FG. Therefore, the erase gate and the word lines at two sides in conventional eFlash will not be connected to a common metal line. Furthermore, the floating gate in eFlash memory is divided into multiple segments in order to form multiple storage units, rather than extends across a whole range of word line like the floating gate in present invention. Besides, a control gate (CG) will be further provided on the floating gate of eFlash memory to control the charge trapping and releasing in the floating gate. In comparison thereto, the floating gate FG of present invention is connected upwardly and directly to the contact CT2. In the aspect of operation, doped regions like channels, source lines and sources/drains are needed in the substrate of eFlash storage units in order to trap charges into floating gate FG through the channel and gate insulating layer to achieve the purpose of non-volatile storage. In comparison thereto, as described above, the structure provided by the present invention is a fully parasitic capacitor, including only the components like word lines WL and floating gates FG as conductive plates and a capacitive dielectric layer 114 to isolate them, without any specific doped regions.

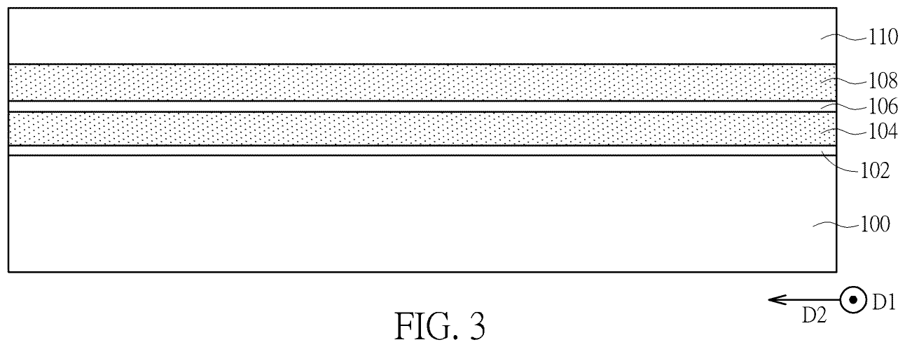

After the capacitor 10 of present invention is described, FIGS. 3-12 will be referred hereinafter to describe explicit manufacturing steps of the capacitor 10 in eFlash process.

Please refer to FIG. 3. In the beginning of the process, a semiconductor substrate 100 is provided to serve as a base for entire capacitor structure. The semiconductor substrate 100 is preferably a Si substrate, ex. a P-type doped Si wafer. Thereafter, a gate insulating layer 102, a floating gate material layer 104, an inter-gate dielectric layer 106, a control gate material layer 108 and a hard mask layer 110 are formed sequentially on the semiconductor substrate 100. Among them, the gate insulating layer 102 may also function as a tunnel oxide layer for eFlash storage device, with material like silicon oxide in a thickness about 90 Å, which may be formed on a surface of the Si substrate through thermal oxide process. The material of floating gate material layer 104 may be polysilicon in a thickness about 400 Å, which may be formed on the gate insulating layer 102 through LPCVD (low pressure chemical vapor deposition). The floating gate material layer 104 is then heavily doped (for example, with N-type dopants like P, As or Sb) and annealed to increase its conductivity, in order to function as a conductive plate for the capacitor. The inter-gate dielectric layer 106 functions as an insulating layer between a control gate and a floating gate in the eFlash, which may be a tri-layer structure composed of silicon oxide-silicon nitride-silicon oxide (ONO) with excellent insulating property with a thickness about 150 Å, which may be in-situ formed by introducing nitrous oxide (N₂O) and ammonia (NH₃) and heating in a furnace. The material of control gate material layer 108 may be polysilicon with a thickness about 800 Å, which may be formed through LPCVD on the inter-gate dielectric layer 106. The material of hard mask layer 110 may be silicon nitride with a thickness about 1500 Å, which may be formed in the same way through LPCVD or PECVD (plasma-enhanced chemical vapor deposition) on the control gate material layer 108.

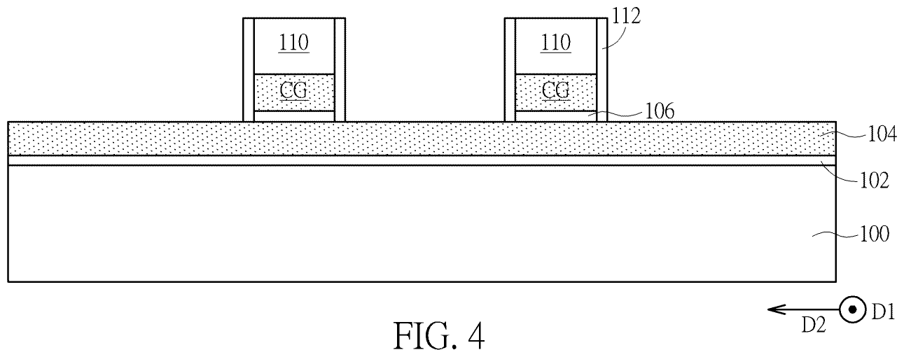

Please refer to FIG. 4. After the aforementioned material layers are formed, a photolithography process is then performed to pattern the hard mask layer 110, control gate material layer 108 and inter-gate dielectric layer 106, so as to form a stack pattern of control gate. Specifically, this step may include forming a photoresist having the stack patterns and performing an anisotropic dry etching process to remove the stack until the floating gate material layer 104 is exposed, so that the control gate material layer 108 therein will be patterned into the control gate CG required by the eFlash memory. After the control gate CG is formed, first spacers 112 are formed on sidewalls of the control gate stack pattern in the second direction D2 to isolate the control gates CG from word lines and erase gates eFlash to be formed later in the eFlash memory. The first spacer 112 may be multilayer structure of silicon oxide and silicon nitride with a thickness about 150 Å, which may be formed by forming a conformal material layer first through thermal oxidation and/or CVD and then performing an etchback process to the conformal material layer. After the first spacers 112 are formed, an ion implantation process may be performed to form doped regions (not shown) required by the word lines of eFlash memory in the semiconductor substrate 100 at two sides of the control gates, to adjust the threshold voltage of word lines. Likewise, those doped regions may or may not be formed in the capacitor of present invention.

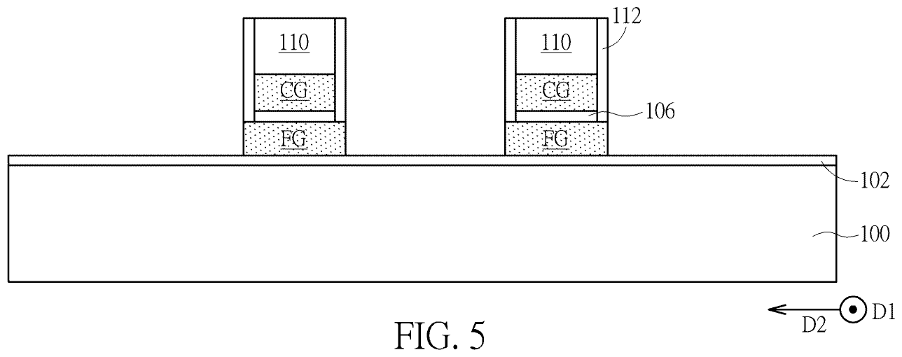

Please refer to FIG. 5. After the control gates CG and first spacers 112 are formed, an anisotropic dry etching process is then performed using the hard mask layer 110 and the first spacers 112 as a mask to remove exposed floating gate material layer 104 until the gate insulating layer 102 is exposed, so that the floating gate material layer 104 will be patterned into multiple floating gates FG. In the case that the capacitor 10 and the eFlash memory are integrally manufactured, the floating gate FG may function as a conductive plate in the capacitor 10 of present invention and as a normal floating gate in the storage device of eFlash memory.

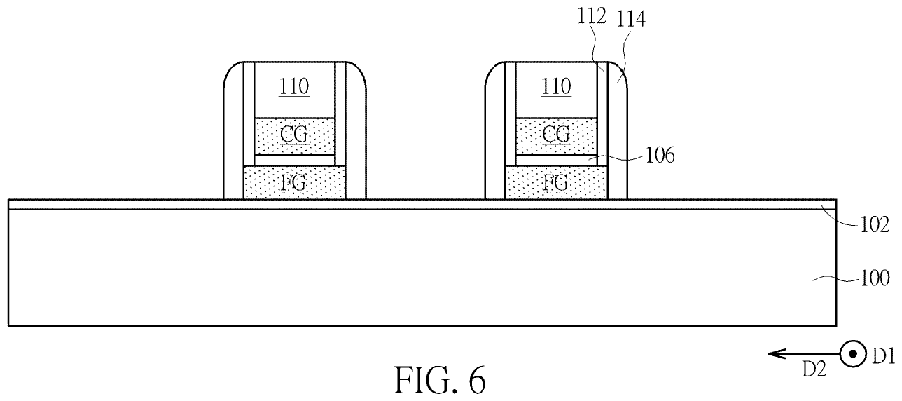

Please refer to FIG. 6. After the floating gates FG are formed, capacitive dielectric layers 114 are then formed on sidewalls of the floating gates FG in the second direction D2. The material of capacitive dielectric layers 114 may be silicon oxide with a thickness about 40 Å-150 Å, which may be formed by forming a conformal oxide layer first on the pattern surface through thermal oxidation and/or CVD and then performing an etchback process to the conformal oxide layer. In the embodiment of present invention, the capacitive dielectric layers 114 function as an insulating layer between two conductive plates(ex. the floating gate FG and word line WL) of the capacitor structure, and at the same time, function as an insulating layer between the control gate/floating gate, word line or the erase gate in eFlash memory structure. After the capacitive dielectric layers 114 are formed, an ion implantation process may be performed to form N-well and/P-well required by the devices in logic region and to form a doped region of source line (not shown) required by eFlash storage device in the semiconductor substrate 100 between the two floating gates FG. Likewise, those doped regions may or may not be formed in the capacitor of present invention.

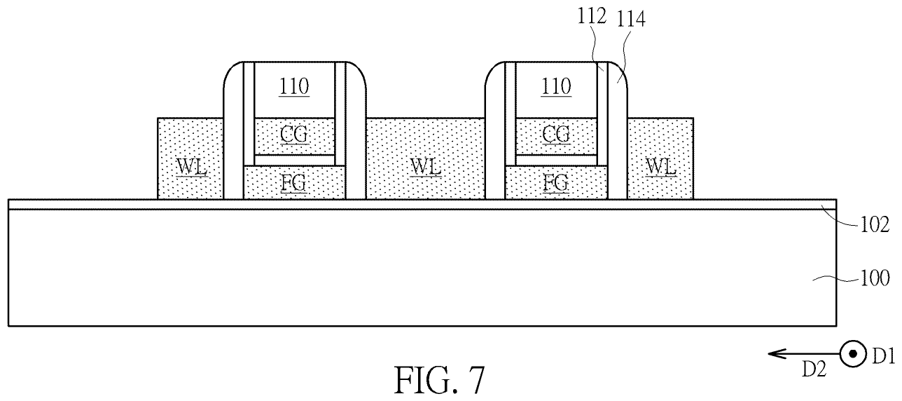

Please refer to FIG. 7. After the capacitive dielectric layers 114 are formed, word lines WL are then formed between the two floating gates FG and at two outer sides of the two floating gates FG in the second direction D2. The material of word line WL may be polysilicon with a thickness about 1000 Å, which is equivalent to the height of control gate CG. The process of manufacturing the word lines may include first depositing a polysilicon layer with a thickness higher than the height of hard mask layer 110 on the substrate through LPCVD, and the polysilicon layer may be heavily doped (ex. with N-type dopants like P, As or Sb) and annealed to increase its conductivity. A CMP (chemical-mechanical planarization) process is then performed to remove parts of the polysilicon layer higher than the hard mask layer 110, so that the top planes of resulting polysilicon layer and hard mask layer 110 will be flush. Thereafter, an etchback process is performed to remove parts of the polysilicon layer, so that the height of polysilicon layer will be lowered to an extent equivalent to the one of control gate CG. The word line WL between the two floating gates is therefore formed in this way. Lastly, a photolithography process is performed to pattern the polysilicon layer at outer sides of the two floating gates FG, so as to form two word lines WL at outer sides of the two floating gates FG. In the embodiment of present invention, the aforementioned polysilicon layer is transformed into the word lines WL of capacitor eventually. However, with respect to the structure of eFlash memory, the polysilicon layer between the two floating gates FG functions as an erase gate. If integrated with logic process, the polysilicon layer on the logic region may also be patterned into the gates required by logic devices in this step. After the word lines WL are formed, an ion implantation process may be performed to form logic devices and LDD (lightly-doped drain) regions required by the eFlash storage devices. Likewise, those doped regions may or may not be formed in the capacitor of present invention.

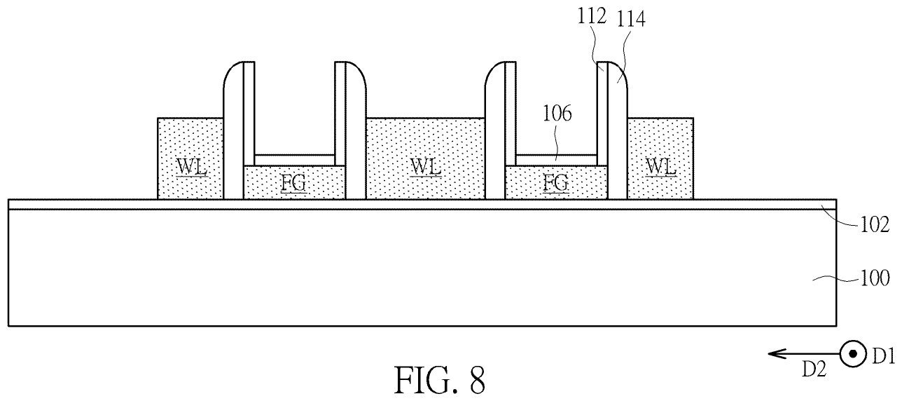

Please refer to FIG. 8. After the word lines WL are formed, remove the hard mask layer 110 and control gate CG above the floating gates. With respect to the capacitor of present invention, the hard mask layer 110 may be removed by performing an etching process using the polysilicon-based word lines WL directly as a mask, while the control gate CG may be removed by performing another photolithography process after the hard mask layers 110 are removed.

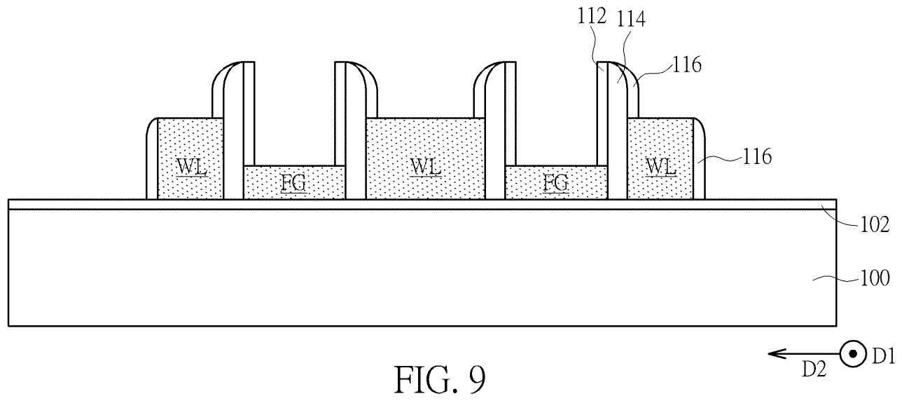

Please refer to FIG. 9. After the hard mask layers 110 and the control gates CG are removed, second spacers 116 are then formed on sidewalls of the capacitive dielectric layers 114 and on sidewalls of outer word lines WL. The material of second spacer 116 may be silicon oxide, silicon nitride or the multilayer structure thereof with a thickness about 70 Å, which may be formed by first forming a conformal silicon oxide layer and/or silicon nitride layer on the pattern surface through thermal oxidation and/or CVD, then performing an etchback process to the conformal layer. The inter-gate dielectric layer 106 on the floating gate FG may also be removed in this etchback process. Please note that since there are control gates blocking on the cell region of eFlash, the inter-gate dielectric layer 106 in the eFlash will not be removed in this step. In addition, doping steps for forming the LDDs in logic region may also be inserted before or after the aforementioned process of second spacers 116. Likewise, those doped regions may or may not be formed in the capacitor of present invention.

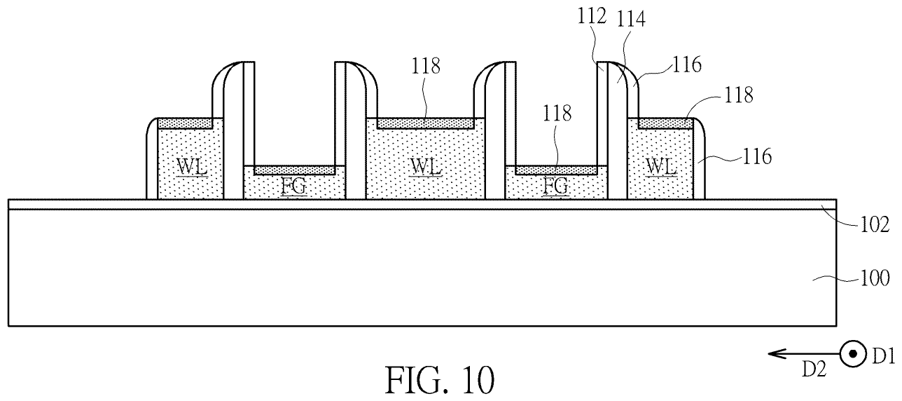

Please refer to FIG. 10. After the second spacers 116 are formed, metal silicide layers 118 are then formed on the top planes of word lines WL and the floating gates FG. The material of metal silicide layers 118 may be NiSi, with its manufacturing steps including forming a self-aligned block (SAB) first to block the substrate regions not for forming the metal silicides, a nickel layer is then sputtered thereon and subject to a rapid thermal process (RTP) to make the nickel react with the exposed polysilicon, so as to form NiSi. The metal silicide layers 118 will be formed on Si-based surface, which includes top planes of the word lines WL and floating gates FG that are not covered by the second spacers 116, top planes of the word lines, control gates and erase gates on the cell region of eFlash, and exposed surfaces of gate, source and drain on the logic region.

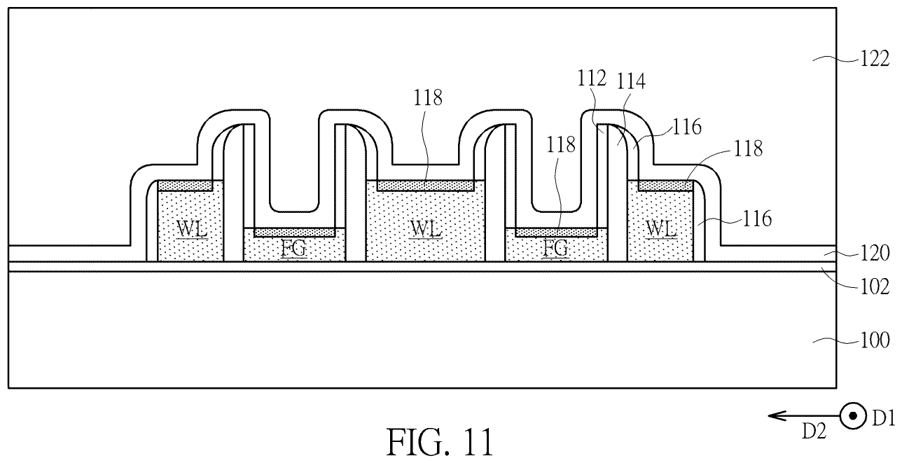

Please refer to FIG. 11. After the metal silicide layers 118 are formed, a liner 120 and an interlayer dielectric layer 122 are then formed on the surface of substrate. The liner 120 is conformally formed on the surface of the aforementioned components, with material like silicon nitride in a thickness about 400 Å. The interlayer dielectric layer 122 is formed on the liner layer 120, covering the whole capacitor 10 and filling up the recesses therein, so as to provide a flat process surface. The material of interlayer dielectric layer 122 may be TEOS with a thickness about 4500 Å, which may be formed through PECVD like the process of liner 120.

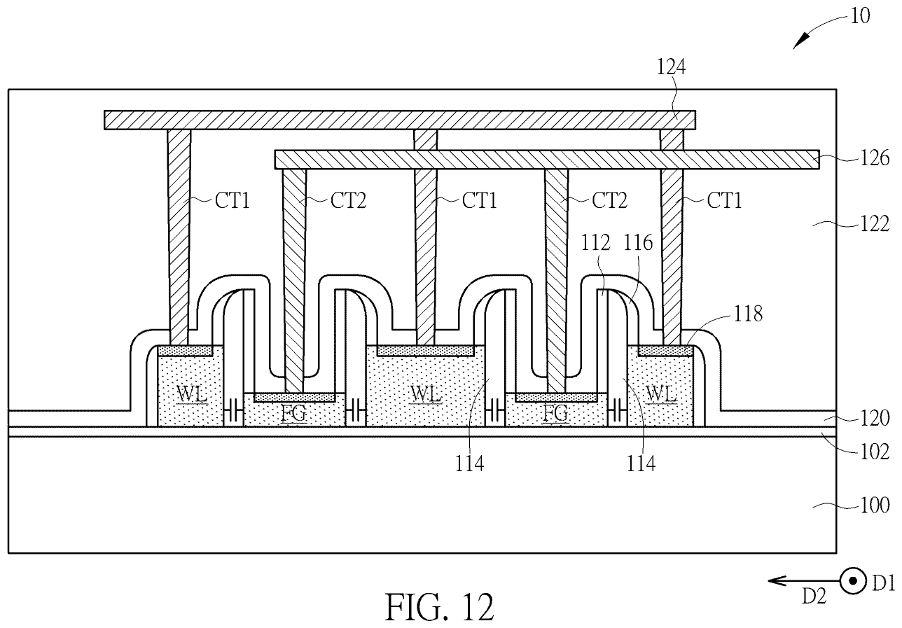

Please refer to FIG. 12. After the liner 120 and interlayer dielectric layer 122 are formed, interconnects like contacts CT1, CT2 and metal lines 124, 126 are then formed in the interlayer dielectric layer 122. The material of contacts CT1, CT2 may be metal like titanium (Ti), titanium nitride (TiN) and tungsten (W), and the manufacturing steps may include first forming contact holes in the interlayer dielectric layer 122 through a photolithography process, then filling those contact holes with metal like Ti, TiN and W, and lastly, performing a CMP process to remove unnecessary metal outsides the contact holes. The material of metal lines 124, 126 may be copper (Cu) or aluminum (Al), which may be formed in the same way as the contacts CT1, CT2. Redundant description is therefore omitted. Please note that in the embodiment of present invention, the metal line 124 and metal line 126 may be in a level of semiconductor BEOL, and the three word lines WL in the capacitor 10 may be connected to a common metal line 124 through corresponding contacts CT1, respectively, and the two floating gates FG in the capacitor 10 may be connected to a common metal line 126 through corresponding contacts CT2, respectively.

It can be known from the aforementioned process that the capacitor of present invention is designed based on eFlash architecture. The process may be compatible and integrated in currently available eFlash process without additional photomask or process steps, which another massive advantage of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitor based on eFlash architecture, comprising:
a substrate;
a first word line, a second word line and a third word line arranged sequentially on said substrate and extending in a first direction;
a first floating gate between said first word line and said second word line and extending continuously in said first direction across a whole range of said first word line and said second word line;
a second floating gate between said second word line and said third word line and extending continuously in said first direction across a whole range of said second word line and said third word line;
multiple capacitive dielectric layers between said three word lines and said two floating gates;
multiple first contacts connected on said first word line, said second word line and said third word line; and
multiple second contacts connected on said first floating gate and said second floating gate;
wherein said capacitor is in reflection symmetry with respect to said second word line, and said second direction is perpendicular to said first direction.

2. The capacitor based on eFlash architecture of claim 1, wherein said first contacts are aligned in said second direction, and said second contact are aligned in said second direction.

3. The capacitor based on eFlash architecture of claim 1, wherein said first contacts are connected to a common metal line, and said second contacts are connected to a common metal line.

4. The capacitor based on eFlash architecture of claim 1, further comprising a gate insulating layer between said three word lines, said two floating gates and said substrate.

5. The capacitor based on eFlash architecture of claim 1, further comprising a liner conformally covering on said three word lines, said two floating gates and said capacitive dielectric layer.

6. The capacitor based on eFlash architecture of claim 5, further comprising an interlayer dielectric layer on said liner.

7. The capacitor based on eFlash architecture of claim 1, further comprising first spacers on sidewalls of said capacitive dielectric layer and on top plans of said two floating gates.

8. The capacitor based on eFlash architecture of claim 1, further comprising second spacers on sidewalls of said capacitive dielectric layer and on top planes of said three word lines, and said second spacers are further on outer sidewalls of said first word line and said third word line.

9. The capacitor based on eFlash architecture of claim 1, wherein a material of said three word lines and said two floating gates is heavily-doped polysilicon.

10. The capacitor based on eFlash architecture of claim 1, wherein said capacitive dielectric layer is silicon oxide layer, silicon nitride layer or the combination thereof.

11. A method of manufacturing a capacitor based on eFlash, comprising:
providing a substrate;
forming a gate insulating layer, a floating gate material layer, an inter-gate dielectric layer and a control gate material layer sequentially on said substrate;
performing a first photolithography process to pattern said control gate material layer and said inter-gate dielectric layer, so as to form a control gate layer stack, wherein control gates are included in said control gate layer stack;
forming first spacers on sidewalls of said control gate layer stack;
performing an etching process using said control gate layer stack and said first spacers as a mask to pattern said floating gate material layer, so as to form a first floating gate and a second floating gate;
forming capacitive dielectric layers on sidewalls of said first spacers and said two floating gates;
forming a first word line and a third word line at outer sides of said two floating gates and forming a second word line between said two floating gates;
removing said control gates and said inter-gate dielectric layers on said two floating gates;
forming an interlayer dielectric layer covering said three word lines and said two floating gates on said substrate; and
forming first contacts and second contacts in said interlayer dielectric layer, said first contacts are connected on said three word lines, and said second contacts are connected on said two floating gates.

12. The method of manufacturing a capacitor based on eFlash of claim 11, further comprising forming a hard mask layer on said control gate material layer, said first photolithography process comprises patterning said hard mask layer, and said step of removing said control gates and said inter-gate dielectric layers on said two floating gates comprises removing said hard mask layer.

13. The method of manufacturing a capacitor based on eFlash of claim 11, further comprising forming second spacers on sidewalls of said capacitive dielectric layers and sidewalls of said first word line and said third word line after said control gates are removed.

14. The method of manufacturing a capacitor based on eFlash of claim 13, further comprising forming metal silicide layers on exposed surfaces of said three word lines and said two floating gates after said second spacers are formed, and said first contacts and said second contacts are connected on said metal silicide layers.

15. The method of manufacturing a capacitor based on eFlash of claim 11, further comprising forming first metal lines and second metal lines after said first contacts and said second contacts are formed, wherein said first contacts are connected to a common said first metal line, and said second contacts are connected to a common said second metal line.

16. The method of manufacturing a capacitor based on eFlash of claim 11, further comprising forming a liner conformally covering said three word lines, said two floating gates and said capacitive dielectric layer before said interlayer dielectric layer is formed.
